(19) United States
(12) Patent Application Publication
(10) Pub. No.: US 2005/0151237 A1
(43) Pub. Date: Jul. 14, 2005

(54) Multi-chip assembly and method for driving the same

(76) Inventors: Kwi Wook Kim, Kyoungki-do (KR); Chang Yeol Lee, Seoul (KR)

Correspondence Address: LADAS & PARRY LLP, 224 SOUTH MICHIGAN AVENUE, SUITE 1200, CHICAGO, IL, 60604, US

(21) Appl. No.: 10/999,415

(22) Filed: Nov. 30, 2004

(30) Foreign Application Priority Data
Jan. 8, 2004 (KR) 2004-1230

(51) Int. Cl. H01L 23/52

(52) U.S. Cl. 257/691

(57) ABSTRACT

Disclosed are a multi-chip assembly and a method for driving the same. The multi-chip assembly includes a first chip designed with a first device driven by a first power source and a second chip designed with a second device driven by a second power source. A power applying section applies first power to the first device of the first chip and a power converting section converts the first power to second power upon receiving the first power from the power applying section and applies the second power to the second device of the second chip. It is possible to provide the multi-chip assembly in the form of a package fabricated by stacking chips designed with mutually different devices driven through a single power source.

### BACKGROUND OF THE INVENTION

1. Field of the Invention

The present invention relates to a multi-chip assembly and a method for driving the same, and more particularly to a stack-type multi-chip assembly and a method for driving the same.

2. Description of the Prior Art

Recently, designs of electronic appliances have tended toward lightness, slimness, and compactness. Therefore, it is important to provide a high-density semiconductor chip package having a lightness, slimness, and compactness structure. To this end, semiconductor packages have been developed in the form of multi-chip assemblies, in which at least two chips are horizontally stacked.

In general, a semiconductor package in the form of a multi-chip assembly is used for receiving chips designed with the same device. Currently, the multi-chip assembly has been developed such that it can receive chips designed with mutually different devices. Accordingly, the multi-chip assembly may allow electronic appliances, such as mobile phones, to be fabricated with lightness, slimness, and compactness structures while simplifying the assembling processes thereof. However, if the semiconductor package is fabricated by stacking chips designed with mutually different devices, a plurality of power sources are necessary in order to drive the devices, respectively.

FIG. 1 is a schematic view for explaining a structure of a power source for applying power to a conventional multi-chip assembly.

Referring to FIG. 1, the conventional multi-chip assembly includes a printed circuit board 10 and first and second chips 12 and 14 mounted on the printed circuit board 10. The first chip 12 is designed with a first device and the second chip 14 is designed with a second device. In addition, the first device of the first chip 12 is driven by a first power source and the second device of the second chip 14 is driven by a second power source. Accordingly, power generated from the first power source is applied to the first device of the first chip 12 and power generated from the second power source is applied to the second device of the second chip 14.

In such a conventional multi-chip assembly fabricated by stacking chips designed with mutually different devices, plural power sources must be provided in order to drive the devices. For this reason, if an electronic appliance is equipped with the conventional multi-chip assembly having chips designed with mutually different devices, a problem may occur because the electronic appliance requires a plurality of power sources for applying power to the devices.

Accordingly, although the conventional multi-chip assembly may allow the electronic appliance to be fabricated with a lightness, slimness, and compactness structure while simplifying assembling processes thereof, the electronic appliance equipped with the conventional multi-chip assembly cannot be easily operated.

### SUMMARY OF THE INVENTION

Accordingly, the present invention has been made to solve the above-mentioned problems occurring in the prior art, and a first object of the present invention is to provide a multi-chip assembly in the form of a package fabricated by stacking chips designed with mutually different devices, which can be driven through a single power source.

A second object of the present invention is to provide a multi-chip assembly in the form of a package fabricated by stacking chips designed with SRAM devices and flash devices, which can be driven through a single power source.

A third object of the present invention is to provide a method for driving a multi-chip assembly in the form of a package fabricated by stacking chips designed with mutually different devices, which can be driven through a single power source.

In order to accomplish the first object, according to the present invention, there is provided a multi-chip assembly comprising: a first chip designed with a first device driven by a first power source; a second chip designed with a second device driven by a second power source; a power applying section for applying the first power source to the first device of the first chip; and a power converting section for converting the first power source upon receiving the first power source from the power applying section to second power source and applying the second power source to the second device of the second chip.

In order to accomplish the second object, according to the present invention, there is provided a multi-chip assembly comprising: a first chip designed with an SRAM device driven by a first power source; a second chip designed with a flash memory device driven by a second power source; a power applying section for applying the first power source to the SRAM device of the first chip; and a power converting section for converting the first power source upon receiving the first power from the power applying section to second power source and applying the second power source to the flash memory device of the second chip.

In order to accomplish the third object, according to the present invention, there is provided a method for driving a multi-chip assembly, the method comprising the steps of:
driving a first device of a first chip by applying a first power source to the first chip designed with the first device;
converting the first power source into second power source; and driving a second device of a second chip by applying the second power source to the second chip designed with the second device.

According to the present invention, it is possible to provide the multi-chip assembly in the form of a package fabricated by stacking chips designed with mutually different devices driven through a single power source. Therefore, the multi-chip assembly of the present invention allows electronic appliance to have compactness, slimness and lightness sizes. In particular, the multi-chip assembly of the present invention can be flexibly installed in various electronic appliances.

### BRIEF DESCRIPTION OF THE DRAWINGS

The above and other objects, features and advantages of the present invention will be more apparent from the following detailed description taken in conjunction with the accompanying drawings, in which:

FIG. 1 is a schematic view for explaining a structure of a power source for applying power to a conventional multi-chip assembly;

FIG. 2 is a schematic view for explaining a structure of a multi-chip assembly according to one embodiment of the present invention;

FIG. 3 is a schematic view for explaining a structure of a multi-chip assembly according to another embodiment of the present invention;

FIG. 4 is a schematic circuit view for explaining a power converting section shown in FIG. 2; and

FIGS. 5a to 5e are schematic sectional views for explaining a method for forming a power converting section shown in FIG. 2.

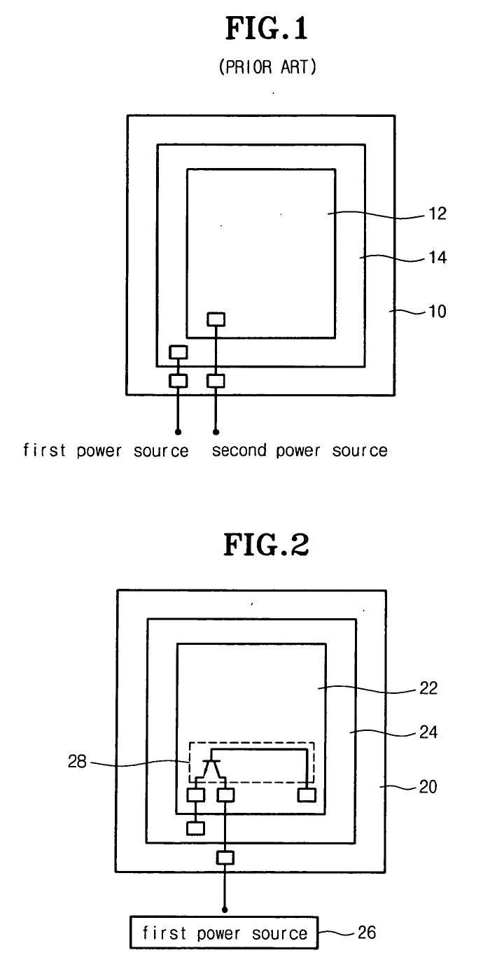

### DETAILED DESCRIPTION OF THE PREFERRED EMBODIMENTS

Hereinafter, the present invention will be described in detail.

A first chip is designed with a first device driven by a first power source. The first chip includes an SRAM device, which is driven by a power source capable of applying voltages of 2.5 to 3.5V to the SRAM device. Preferably, the SRAM device is driven by a power source applying voltages of 3V to the SRAM device. In addition, a second chip is designed with a second device driven by a second power source. The second chip includes a flash memory device, which is driven by a power source capable of applying voltages of 1.6 to 2.0V to the flash memory device. Preferably, the flash memory device is driven by a power source applying voltages of 1.8V to the flash memory device.

In addition, the multi-chip assembly includes a printed circuit board and first and second chips mounted on the printed circuit board. Preferably, the first chip is stacked on the second chip. However, it is also possible to stack the second chip on the first chip.

The multi-chip assembly includes a power applying section and a power converting section for applying power to the first and second devices through a single power source. The power applying section applies first power to the first device of the first chip. In addition, the power converting section converts the first power into second power such that the second power is applied to the second device of the second chip. The power converting section preferably includes a CMOS transistor or a bipolar junction transistor. In addition, the power converting section is preferably formed in the first chip, the second chip or the printed circuit board.

According to the multi-chip assembly of the present invention, the first power is applied to the first device of the first chip so that the first device of the first chip is driven. Then, after converting the first power into the second power, the second power is applied to the second device of the second chip so that the second device of the second chip is driven. Accordingly, the multi-chip assembly in the form of a package fabricated by stacking chips designed with mutually different devices can be driven through a single power source.

In the meantime, it is also possible to convert the second power to the first power after primarily applying the second power to the second device of the second chip.

Hereinafter, the present invention will be described in detail with reference to accompanying drawings.

FIG. 2 is a schematic view for explaining a structure of a multi-chip assembly according to one embodiment of the present invention.

Referring to FIG. 2, the multi-chip assembly of the present invention includes a printed circuit board 20. A second chip 24 is stacked on the printed circuit board 20 and a first chip 22 is mounted on the second chip 24. The first chip 22 is designed with an SRAM device driven by a power source applying voltages of about 3V and the second chip 24 is designed with a flash memory device driven by a power source applying voltages of about 1.8V.

Accordingly, the power applying section 26 acts as a first power source applying voltages of about 3V to the first chip 22 in order to drive the SRAM device of the first chip 22. In addition, the voltages of about 3V are also applied to the power converting section 28. Upon receiving the voltages of about 3V from the power applying section 26, the power converting section 28 converts the voltages of about 3V into voltages of about 1.8V and applies the voltages of about 1.8V to the second chip 24 in order to drive the flash memory device of the second chip 24.

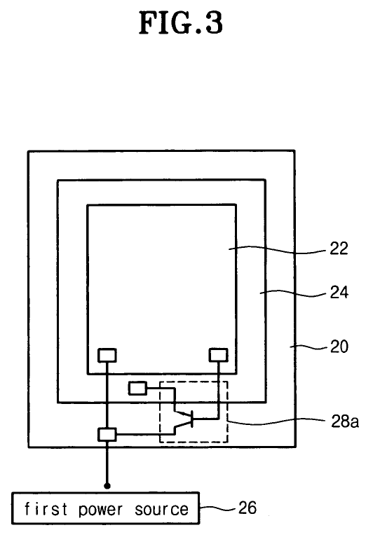

The power converting section 28 is formed in the first chip 22. However, as shown in FIG. 3, it is also possible to provide a power converting section 28a on the printed circuit board 20 or on the second chip 24.

Although it has been described that the power applying section 26 applies power to the first chip 22 and the power converting section 28 applies power to the second chip 24, it is also possible to allow the power applying section 26 to apply the power to the second chip while allowing the power converting section 28 to apply power to the first chip. In addition, although it has been described that the first chip is stacked on the second chip, it is also possible to stack the second chip on the first chip.

In this manner, the multi-chip assembly can drive the first and second chips 22 and 24 through a single power source by using the power converting section.

Herein, the multi-chip assembly employs a CMOS transistor as the power converting section if relatively low power consumption is required or employs a bipolar junction transistor as the power converting section if relatively high power consumption is required.

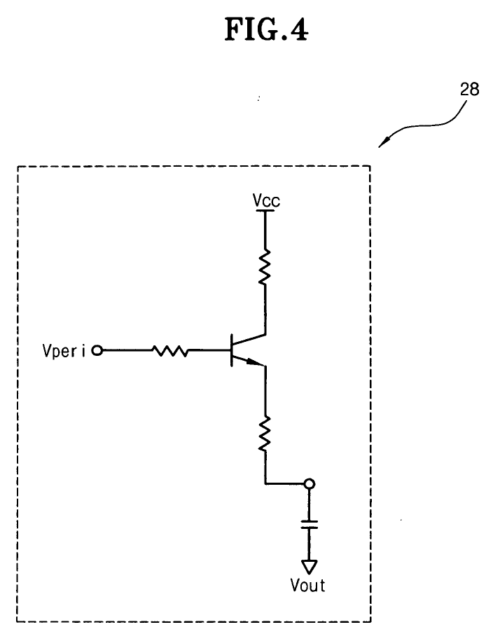

Hereinafter, the power converting section 28 in the form of the bipolar junction transistor will be described with reference to FIG. 4. The bipolar junction transistor has an NPN structure. Therefore, the bipolar junction transistor applies power of about 3V through a Vcc so as to drive the SRAM of the first chip. In addition, the power of about 3V is applied to a collector of the bipolar junction transistor. Also, the bipolar junction transistor employs a Vperi of about 2.5V as a base. Accordingly, power of about 1.8V is outputted through a Vout. In addition, the power outputted from the Vout is applied to the second chip so as to drive the flash memory device.

There fore, the SRAM device of the first chip and the flash memory device of the second chip can be driven through the single power source.

At this time, if the power converting section is embodied in the form of the bipolar junction transistor, it is necessary to compensate for temperature variation in order to stably apply the power. Herein, if the voltage outputted through the bipolar junction transistor is ΔVout, the ΔVout satisfies following Equation 1.
ΔVout=ΔVₜₕₑᵣₘₐₗ₁+ΔVₜₕₑᵣₘₐₗ₂+ΔV_{load} Equation 1

The ΔVₜₕₑᵣₘₐₗ₁ denotes a voltage reduction value of a base-emitter junction caused by the temperature. In particular, when taking the thermal coefficient of about −2.0 mV/° C. and a peripheral temperature range of about −40 to 85° C., a maximum of the ΔVₜₕₑᵣₘₐₗ₁ is about +0.25V. In addition, the ΔVₜₕₑᵣₘₐₗ₂ denotes variation with regard to the temperature of the Vperi. The ΔVₜₕₑᵣₘₐₗ₂ is expected as +2.3 mV/° C. Also, the ΔV_{load} is expected as 0.3V in relation to variation of 10 μA to 70 m.

Herein, the ΔVₜₕₑᵣₘₐₗ₁ is a unique characteristic of the base-emitter junction, so it is difficult to adjust the ΔVₜₕₑᵣₘₐₗ₁. Accordingly, the temperature compensation must be carried out through adjusting the ΔVₜₕₑᵣₘₐₗ₂. To this end, the proportion of resistors having positive thermal coefficients to semiconductor devices having negative thermal coefficients is properly adjusted so as to obtain the temperature characteristic of about −2.0 mV/° C. In this case, it is possible to apply power having stable voltage.

As mentioned above, the present invention can apply stable drive power to the first and second chips even if the first chip or the second chip generates a high temperature by sufficiently compensating for the temperature of the power converting section.

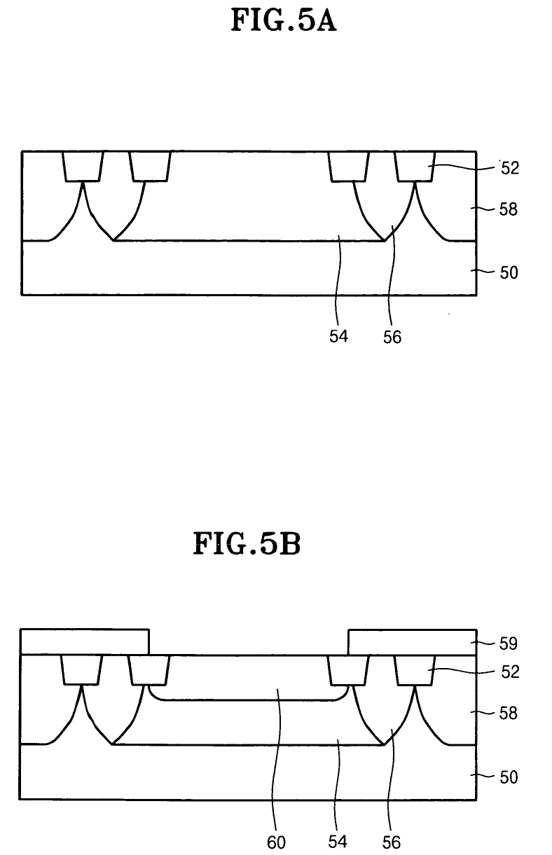

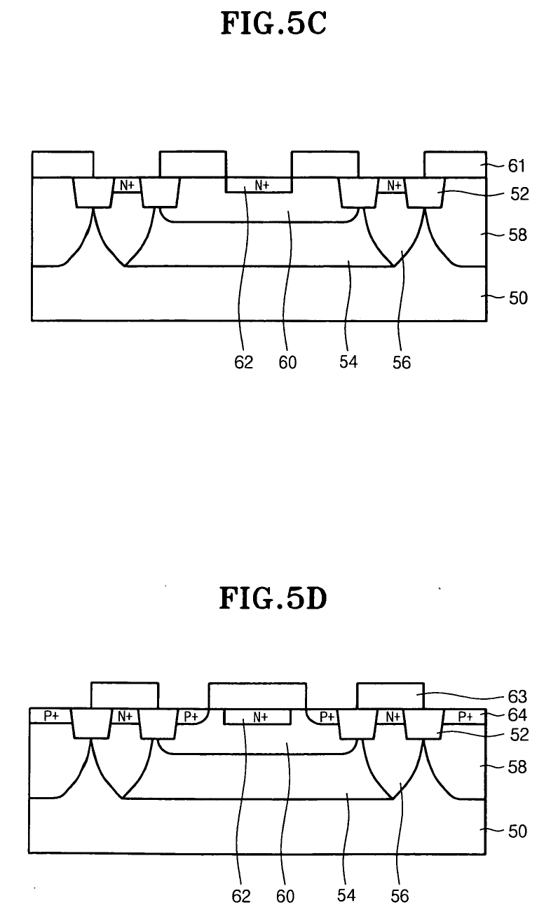

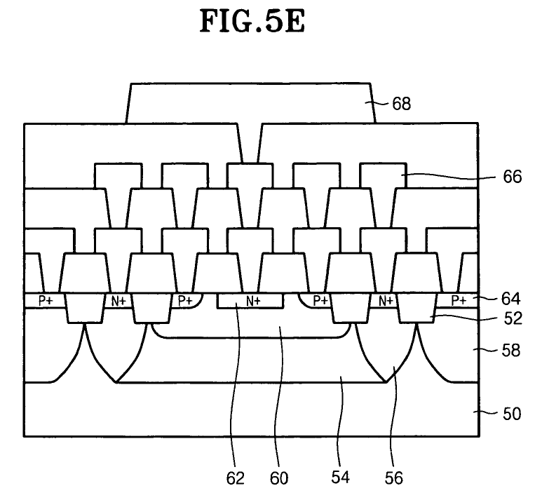

Hereinafter, the power converting section in the form of the bipolar junction transistor will be described with reference to FIGS. 5a to 5e.

Referring to FIG. 5a, an isolation layer 52 is formed on a substrate 50. At this time, a trench isolation layer is used for the isolation layer 52. Then, an N-well having a deep junction is formed. While forming the N-well, an ion implantation process is carried out in order to form a buried collector 54. The ion implantation process is carried out with the condition of P31. In addition, ion implantation process is carried out with the dose amount of about 1E13/cm³ to 2E13/cm³ and ion energy of about 1.0 to 1.5 MeV. In addition, a P-well 58 is formed after forming a collector plug 56.

Referring to FIG. 5b, a base 60 is formed through performing the ion implantation process using a photoresist pattern 59 as an ion mask. At this time, the ion implantation process is carried out with the dose amount of about 1E13/cm³ to 4E13/cm³ and ion energy of about 10 to 20 KeV. In addition, it is also possible to form the base 60 through performing the ion implantation process with B11 of about 2.5E12⁴/cm³ to 1E13⁴/cm³ and ion energy of about 10 to 25 KeV without using the photoresist pattern 59.

Referring to FIG. 5c, an emitter and a collector pickup 62 are formed by performing the ion implantation process using a photoresist pattern 61 as an ion mask. At this time, the ion implantation process is carried out by using As gas with the dose amount of about 3E15/cm³ to 6E15/cm³ and ion energy of about 25 to 35 KeV.

Referring to FIG. 5d, a base pickup 64 is formed by performing the ion implantation process using a photoresist pattern 63 as an ion mask. At this time, the ion implantation process is carried out by using BF₂ gas with the dose amount of about 2E15/cm³ to 4E15/cm³ and ion energy of about 15 to 25 KeV.

Referring to FIG. 5e, a process for forming a general bipolar junction transistor is carried out. Accordingly, the base and the collector are connected to a first metal wiring 66 and the emitter is connected to a second metal wiring.

Thus, the power converting section of the multi-chip assembly in the form of the bipolar junction transistor can be formed through performing the above processes.

As described above, the present invention can provide a multi-chip assembly in the form of a package fabricated by stacking chips designed with mutually different devices, which can be driven through a single power source. Therefore, the multi-chip assembly can be used with various kinds of power sources without limitation, so the multi-chip assembly can be employed in various electronic appliances. In particular, the multi-chip assembly can be fabricated with the SRAM device and the flash memory device.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A multi-chip assembly comprising:
a first chip designed with a first device driven by a first power source;
a second chip designed with a second device driven by a second power source;
a power applying section for applying the first power source to the first device of the first chip; and
a power converting section for converting the first power source upon receiving the first power from the power applying section to second power source and applying the second power source to the second device of the second chip.

2. The multi-chip assembly as claimed in claim 1, wherein the first chip is stacked on the second chip.

3. The multi-chip assembly as claimed in claim 2, further comprising a printed circuit board for mounting the second chip thereon.

4. The multi-chip assembly as claimed in claim 1, wherein the power converting section includes a CMOS transistor or a bipolar junction transistor.

5. The multi-chip assembly as claimed in claim 1, wherein the power converting section is provided in the first chip, the second chip or a printed circuit board.

6. A multi-chip assembly comprising:
a first chip designed with an SRAM device driven by a first power source;
a second chip designed with a flash memory device driven by a second power source;
a power applying section for applying the first power source to the SRAM device of the first chip; and
a power converting section for converting the first power source upon receiving the first power from the power applying section to second power source and applying the second power source to the flash memory device of the second chip.

7. The multi-chip assembly as claimed in claim 6, further comprising a printed circuit board for mounting the second chip thereon, wherein the first chip is stacked on the second chip.

8. The multi-chip assembly as claimed in claim 7, wherein the power converting section is provided in the first chip, the second chip or the printed circuit board, and includes a CMOS transistor or a bipolar junction transistor.

9. The multi-chip assembly as claimed in claim 6, wherein the first power is a voltage of about 2.5 to 3.5V, and the second power is a voltage of about 1.5 to 2.0V.

10. A method for driving a multi-chip assembly, the method comprising the steps of:
driving a first device of a first chip by applying a first power source to the first chip designed with the first device;
converting the first power source into second power source; and
driving a second device of a second chip by applying the second power source to the second chip designed with the second device.
